(19) United States
(12) Patent Application Publication
(10) Pub. No.: US 2013/0168140 A1
(43) Pub. Date: Jul. 4, 2013

(54) Printed Circuit Board and Method of Manufacturing Same

(71) Applicants: PEKING UNIVERSITY FOUNDER GROUP CO., LTD., Beijing (CN); ZHUHAI FOUNDER TECH. HI-DENSITY ELECTRONIC CO., LTD., Zhuhai City (CN)

(72) Inventors: Xianren CHEN, Beijing (CN); Lianghong LIAO, Beijing (CN); Xin CHEN, Beijing (CN); Yongshuan HU, Beijing (CN)

(73) Assignees: ZHUHAI FOUNDER TECH. HI-DENSITY ELECTRONIC CO., LTD., Zhuhai City (CN); PEKING UNIVERSITY FOUNDER GROUP CO., LTD., Beijing (CN)

(21) Appl. No.: 13/730,149

(22) Filed: Dec. 28, 2012

(30) Foreign Application Priority Data
Dec. 28, 2011 (CN) 201110446896.2

(51) Int. Cl. H05K 3/00; H05K 1/02

(52) U.S. Cl. CPC H05K 3/0044; H05K 1/02
USPC 174/255; 409/131

(57) ABSTRACT

A method of manufacturing a printed circuit board (PCB) is provided. The method includes defining an area on the PCB to be subjected to a controlled-depth milling. The area includes a warp. The method further includes providing a plurality of positioning holes adjacent to edges of the area of the PCB, installing positioning members in the positioning holes so as to fix the PCB on a flat surface of a table of a milling equipment, and milling the area of the PCB. A PCB is also provided. The PCB includes a controlled-depth area containing patterns and having a surface lower than a surface of the PCB. The PCB further includes a plurality of positioning holes formed adjacent to edges of the controlled-depth area.

### CROSS REFERENCE OF RELATED APPLICATIONS

This application claims the benefit of Chinese Patent Application No. 201110446896.2, filed on Dec. 28, 2011, which is incorporated by reference in its entirety.

### FIELD

The present disclosure relates to the technical field of manufacturing a printed circuit board, and particularly to a method of positioning a printed circuit board for milling and a printed circuit board.

### BACKGROUND

A manufacturing process for a Printed Circuit Board (PCB) generally includes: blanking; inner layer manufacturing; laminating; hole drilling; copper plating; outer layer manufacturing; solder mask printing; character printing; surface treatment; and shape processing. Certain portion of a PCB may be warped due to thermal stress, chemical factors, improper processing and other influences in the manufacturing processes. In addition, a warped substrate that is used as a component of a PCB may cause the PCB to warp. Warping in a PCB can result in a poor contact between electronic elements and PCB welding spots or a failure to install electronic elements on the PCB.

### SUMMARY

According to one embodiment, a method of manufacturing a printed circuit board (PCB) is provided. The method includes defining an area on the PCB to be subjected to a controlled-depth milling. The area may include a warp. The method further includes providing a plurality of positioning holes around the area of the PCB, for example, adjacent to edges of the area of the PCB, installing positioning members in the positioning holes so as to fix the PCB on a flat surface of a table of a milling equipment, and milling the area of the PCB.

In some embodiments, a method of manufacturing a PCB may further include determining whether the warp exceeds a predetermined threshold. The threshold may be more than or equal to 5%.

In one embodiment, a method of manufacturing a PCB may further include placing a gasket between each of the positioning members and the PCB.

In some embodiments, each of the positioning members includes a fastener and a gasket. The fastener may be a screw having a diameter matched with a diameter of a corresponding positioning hole and having a length which is 1-2 mm longer than a sum of a thickness of the PCB and a thickness of the gasket. Each of the positioning members may include more than one gasket. A sum of thicknesses of gaskets may be more than or equal to 1 mm. Gaskets may be manufactured by interweaving a paper pulp and a fiber. Gaskets may have a hardness of 70±5 degrees according to SHORE D hardness scale.

According to one embodiment, a PCB is also provided. The PCB includes a controlled-depth area containing patterns and having a surface lower than a surface of the PCB. The PCB further includes a plurality of positioning holes formed adjacent to edges of the controlled-depth area.

In some embodiments, the positioning holes may be round-shaped through holes having a diameter more than or equal to 3.2 mm and less than or equal to 6.5 mm. A distance between the positioning holes and adjacent edges of the controlled-depth area may be more than or equal to 3 mm and less than or equal to 10 mm.

In some embodiments, a number of the positioning holes may be determined by a shape of the controlled-depth area. A number of the positioning holes may be at least three. The positioning holes may be non-plating through holes.

### BRIEF DESCRIPTION OF THE DRAWINGS

Reference will now be made, by way of example, to the accompanying drawings which show example embodiments of the present application, and in which:

FIG. 1 shows a schematic flowchart of a method of manufacturing a PCB according to one embodiment of this disclosure;

FIG. 2 shows a schematic diagram of a PCB according to one embodiment of this disclosure;

FIG. 3 shows a schematic diagram of a PCB on a milling table according to one embodiment of this disclosure;

FIG. 4 shows a schematic diagram of a PCB on a milling table according to one embodiment of this disclosure; and

FIG. 5 shows a schematic diagram of a PCB on a milling table according to one embodiment of this disclosure.

In the drawings: reference number 1 denotes a printed circuit board; reference number 2 denotes a table of a milling equipment; reference number 3 denotes a controlled-depth area; reference number 4 denotes a positioning hole; reference number 5 denotes a positioning member; reference number 6 denotes a gasket.

### DETAILED DESCRIPTION OF THE EMBODIMENTS

For better understanding of those skilled in the art on the technical solution of the present disclosure, the embodiments will be further described in details below with reference to the accompanying drawings.

A controlled-depth milling process is a method of milling within a specified area on a PCB to form a variety of patterns which have a particular requirement on depth. A PCB manufactured with a controlled-depth milling process may not be completely milled through. When in controlled-depth milling process, a warped PCB may not be in close contact with a table surface of a milling equipment, thus decreasing the precision of the milling on the PCB severely. However, the tolerance of depth has been strictly limited in performing a milling on a PCB. Further, no good solutions to alleviate warping of a PCB has been found. Therefore, the precision of a controlled-depth milling on a warped PCB fails to meet a high precision requirement.

In one embodiment, a method for positioning a PCB in a controlled-depth milling process is provided. First, several positioning holes for positioning a PCB on a processing table are arranged on peripheral areas of the PCB. For example, the positioning holes can be randomly arranged on the peripheral areas of the PCB. Subsequently, the PCB is positioned on a processing table using the positioning holes. Specifically, positioning members are inserted in the positioning holes so that a PCB may be fastened on the processing table. An area to be milled is defined and milling is performed on the defined area of the PCB. In a controlled-depth milling, the PCB is not necessarily milled through. That is, a controlled-depth milling may not produce a through hole in a PCB. However, if the defined area includes a warped portion, the depth control of a controlled-depth milling may not be precise.

Thus, in another embodiment, a PCB milling process may include:

1) defining an area of a PCB for depth control;

2) providing positioning holes around the defined area; for example, providing positioning holes adjacent to edges of the defined area;

3) positioning the PCB on a processing table by inserting positioning members into the positioning holes to fix the PCB on the table; and

4) milling the PCB at the defined area (controlled-depth area). After milling, a thickness of the defined area may be smaller than a thickness of the PCB and a surface of the defined area may be lower than a surface of the PCB.

A printed circuit board produced according to these steps includes a controlled-depth area containing patterns formed by milling the PCB. The PCB further includes a plurality of positioning holes arranged to be adjacent to the controlled-depth area. The positioning holes are used for fixing the PCB on a flat surface of a table of a milling equipment through positioning members. Positioning members are installed in corresponding positioning holes and penetrate through the positioning holes so as to improve the milling precision.

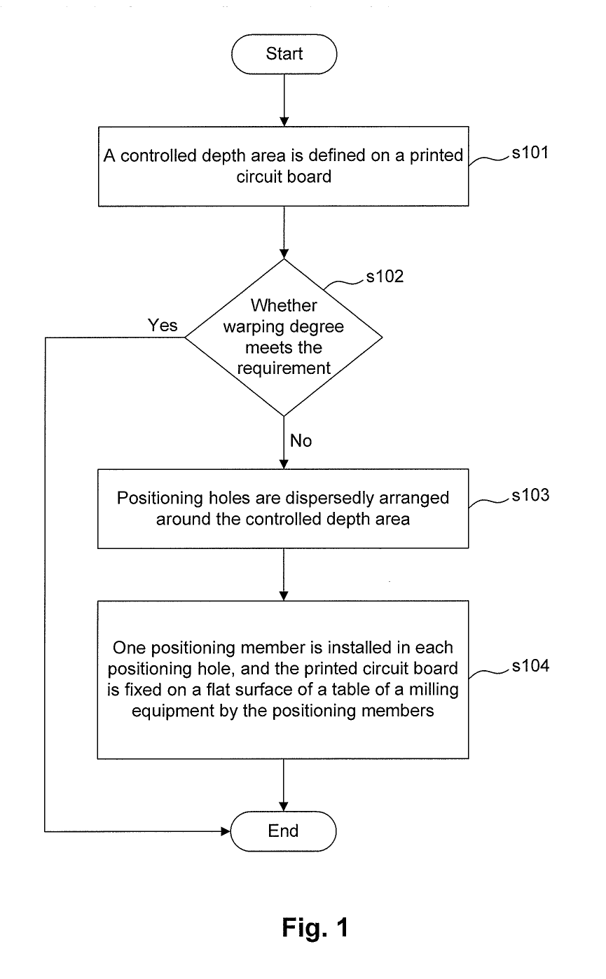

A detailed embodiment is illustrated in FIG. 1. A method of milling a PCB to form a controlled-depth area may include the following steps:

At step s101, a controlled-depth area is defined on a PCB to be milled to a predetermined depth according to a predetermined design rule;

At step s102, the PCB to be milled is inspected. If it is determined that the warp of the PCB (warping degree) does not exceed a predetermined threshold, for example, more than or equal to 5%, the PCB may be mounted on a mill table according to regular mounting method. The PCB may then be milled to form a controlled-depth area. However, if the warp of the PCB exceeds the predetermined threshold, for example, more than or equal to 5%, the process moves to step s103.

At step s103, a plurality of positioning holes are dispersedly arranged around the controlled-depth area. In one embodiment, at least 3 positioning holes are provided on the PCB. Three positioning holes not only may reduce warping of the PCB and thus improve milling precision, but also prevent technical staff from placing the surface incorrectly for milling. The flatness of the PCB can be improved during milling by arranging more positioning holes around the controlled-depth area so long as such arrangement is practical in design. If the PCB can be fixed on the processing table without much warp, the precision to control milling depth can be improved.

At step s104, one positioning member is installed in each positioning hole. Thus, the number of the positioning holes is identical to that of the positioning members. The PCB is fixed on a flat surface of a table of a milling equipment by the positioning members. Subsequently, milling at the controlled-depth area can be performed.

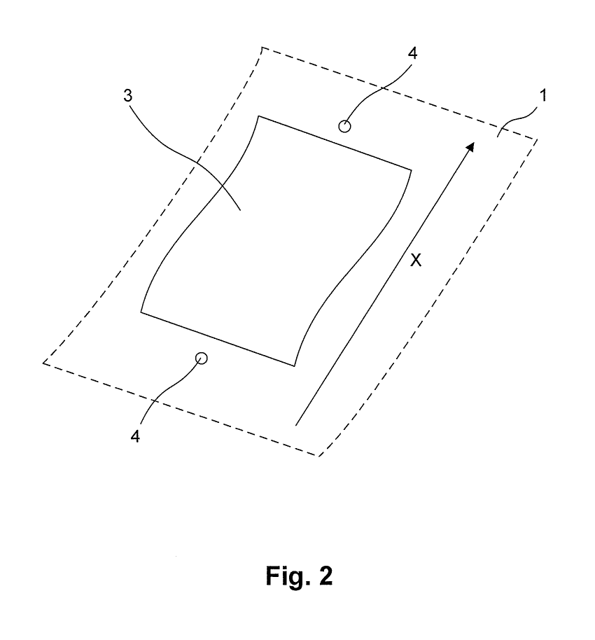

In another embodiment, the number of the positioning holes may be two. For example, when the warping occurs mainly in one direction, e.g. an X direction as shown in FIG. 2, two positioning holes 4 may be arranged to locate outside two edges of the controlled-depth area 3 of PCB 1.

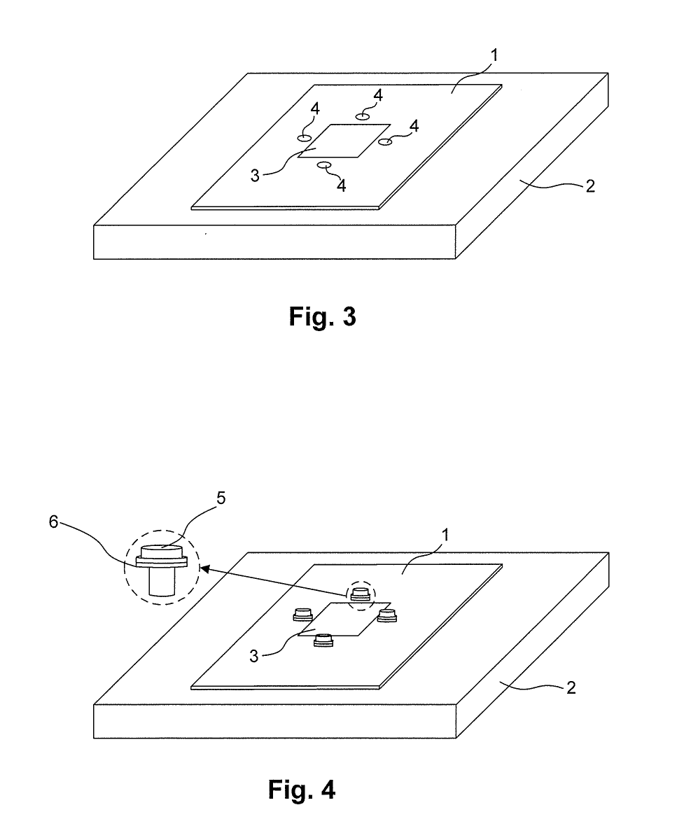

FIG. 3 shows another embodiment of this disclosure. As illustrated in FIG. 3, a controlled-depth area 3 is defined in a rectangular shape and is located in a center portion of PCB 1. However, the size, shape, and location of controlled-depth area 3 are not particularly limited. A location of controlled-depth area 3 may be located in the periphery of PCB 1 or other locations according to needs and designs. Four positioning holes 4 are dispersedly arranged around the controlled-depth area 3 so as to position PCB 1 more precisely. The number of the positioning holes 4 is not limited. In one embodiment, at least three positioning holes are provided adjacent to controlled-depth area 3.

In one embodiment, positioning holes may be round-shaped through holes, each having a diameter of more than or equal to 3.2 mm and less than or equal to 6.5 mm. A distance between a positioning hole and an adjacent edge of a controlled-depth area may be more than or equal to 3 mm and less than or equal to 10 mm. The distance may be obtained by making a line including a positioning hole perpendicular to a closest edge of a controlled-depth area. A length of the line between the positioning hole and the closest edge can be defined as the distance. A distance so chosen may ensure that a milling cutter of a milling equipment would not inadvertently traverse positioning members 5 (see FIG. 4) placed in the positioning holes 4. On the other hand, the distance between positioning holes 4 and controlled-depth area 3 may not be more than 10 mm in order to fix a warped PCB. If the distance is more than 10 mm, a warped PCB may not be flattened on a processing table 2 to a satisfactory degree. In some embodiments, positioning holes 4 are Non Plating Through Holes (NPTHs), e.g., the surface of positioning holes 4 is not plated with metal layer. In other embodiments, position holes 4 may be plated with conducting materials.

Referring to FIG. 4, positioning members 5 may be a fastener. In some embodiments, a gasket 6 may be added to protect the surface of the PCB from being scratched during fastening of positioning member 5. Gasket 6 may be placed between positioning members 5 and PCB 1. In another embodiment, positioning member 5 may be a screw. The screw may have a diameter matched with the diameter of positioning hole 4. The screw may have a length which is more than the sum of the thickness of the PCB 1 and the thickness of the gasket 6 so that the screw may be connected to table 2 to securely fix PCB 1 to table 2. For example, the screw has a length which is 1-2 mm longer than the sum of the thickness of PCB 1 and the thickness of gasket 6.

Further, blind holes (not shown) may be arranged on table 2 to receive positioning member 5. For example, a number of blind holes may be arranged on table 2 so that there are as many blind holes as positioning holes 4. A diameter of the blind holes is designed to match the diameter of positioning member 5. A length of a blind hole may be longer than the part of the screw that protrudes from PCB 2 and gasket 6, e.g. 1-2 mm longer. An inner thread of a blind hole matches an outer thread of positioning member 5 so that a front end of each screw may stretch into and is fixed in the blind hole.

In one embodiment, one or more gaskets may be used with a positioning member. When one gasket is used, the thickness of the gasket may be more than or equal to 1 mm. When a plurality of gaskets is used with one positioning member, a sum of thicknesses of the gaskets may be more than or equal to 1 mm. For example, two gaskets each having a thickness of 0.5 mm may be used with one positioning member.

In some embodiments, a gasket can be made by interweaving a paper pulp and a fiber. A gasket may have a hardness of 70±5 degrees based on SHORE D hardness scale. The thickness and hardness of a gasket may be designed to prevent a gasket from failure to protect the surface of PCB 1. That is, if a gasket is broken, a positioning member 5 may scratch the surface of PCB 1.

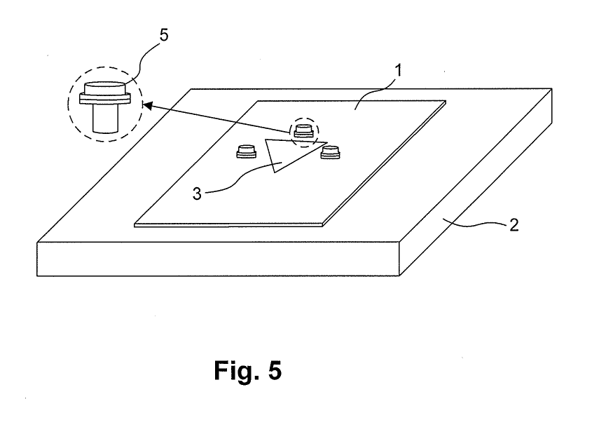

In one embodiment, a PCB is provided. The PCB may include a controlled-depth area (controlled-depth area 3 in FIGS. 2-4). The area may have a thickness smaller than the rest of the PCB. The controlled-depth area may contain patterns formed in a controlled depth and have a surface lower than a surface of the PCB. The PCB may further include a plurality of positioning holes 4 (FIGS. 2-3) arranged around and adjacent to the edges of the controlled-depth area 3. The positioning holes 4 are used for fixing the PCB on a flat surface of a table 2 (FIGS. 3-5) of a milling equipment through positioning members 5 (FIGS. 4-5).

In some embodiments, positioning holes 4 are round-shaped through holes each having a diameter more than or equal to 3.2 mm and less than or equal to 6.5 mm. A distance between a positioning hole and an adjacent edge of a controlled-depth area may be more than or equal to 3 mm and less than or equal to 10 mm.

In another embodiment, the controlled-depth area is a triangular area. With reference to FIG. 5, three positioning members 5 are arranged around the controlled-depth area 3. Specifically, position members 5 are respectively arranged adjacent to three edges of the triangular controlled-depth area 3. Thus, a number of positioning holes may be determined according to a shape of the controlled-depth area 3.

Other methods, structures, and effects similar to those disclosed above may be applied to the embodiment illustrated in FIG. 5, and thus a description thereof will be omitted here.

Certain adaptations and modifications of the described embodiments can be made. Therefore, the above discussed embodiments are considered to be illustrative and not restrictive.

What is claimed is:

1. A method of manufacturing a printed circuit board (PCB), comprising:
defining an area on the PCB to be subjected to a controlled-depth milling, wherein the area includes a warp;
providing a plurality of positioning holes adjacent to edges of the area of the PCB;
installing positioning members in the positioning holes to fix the PCB on a flat surface; and
milling the area of the PCB.

2. The method of claim 1, further comprising:
placing a gasket between each of the positioning members and the PCB.

3. The method of claim 1, wherein the number of the positioning holes is at least three, and the positioning holes are dispersedly arranged around the area.

4. The method of claim 1, wherein each of the positioning members comprises a fastener and a gasket.

5. The method of claim 4, wherein each of the positioning members comprises one or more gasket, a sum of thicknesses of the one or more gasket is more than or equal to 1 mm; and the one or more gasket is manufactured by interweaving a paper pulp and a fiber.

6. The method of claim 4, wherein the gasket has a hardness of 70±5 degrees according to SHORE D hardness scale.

7. A method of manufacturing a printed circuit board (PCB), comprising:
defining an area on the PCB to be subjected to a controlled-depth milling;
determining whether a warping degree of the area exceeds a predetermined threshold;
if the warping degree of the area exceeds the predetermined threshold,
providing a plurality of positioning holes adjacent to edges of the area of the PCB;
installing positioning members in the positioning holes to fix the PCB on a flat surface; and
milling the area of the PCB;
if the warping degree of the area does not exceed the predetermined threshold,
milling the area of the PCB.

8. The method of claim 7, wherein the threshold is more than or equal to 5%.

9. The method of claim 7, wherein the number of the positioning holes is at least three, and the positioning holes are dispersedly arranged around the area.

10. A printed circuit board (PCB), comprising
a controlled-depth area containing patterns and having a surface lower than a surface of the PCB; and
a plurality of positioning holes formed adjacent to edges of the controlled-depth area.

11. The PCB of claim 10, wherein the positioning holes are round-shaped through holes having a diameter more than or equal to 3.2 mm and less than or equal to 6.5 mm.

12. The PCB of claim 10, wherein a distance between the positioning holes and adjacent edges of the controlled-depth area is more than or equal to 3 mm and less than or equal to 10 mm.

13. The PCB of claim 10, wherein a number of the positioning holes is determined by a shape of the controlled-depth area.

14. The PCB of claim 10, wherein a number of the positioning holes is at least three.

15. The PCB of claim 10, wherein the positioning holes are non-plating through holes.
